(19) United States
(12) Patent Application Publication
(10) Pub. No.: US 2025/0155520 A1
(43) Pub. Date: May 15, 2025

(54) AUTOMATED DIGITAL WIRING HARNESS ASSEMBLY AND TESTING STATIONS

(71) Applicant: VOLEX PLC, SAN YSIDRO, CA (US)

(72) Inventor: Francisco Antonio Jiménez Celis, Tijuana (MX)

(21) Appl. No.: 18/945,091

(22) Filed: Nov. 12, 2024

Related U.S. Application Data
(60) Provisional application No. 63/598,202, filed on Nov. 13, 2023.

(51) Int. Cl. G01R 31/58; H01B 13/012

(52) U.S. Cl. CPC G01R 31/58; H01B 13/01209; H01B 13/01236

(57) ABSTRACT

Aspects of the present disclosure include digital wire harness assembly stations, and automated testing techniques. Examples include systems and methods for assembling and testing wire harnesses. A wire harness assembly system may include a display, a screen, a cable connector mount, an electrical testing unit, and at least one computing device to execute a test program associated with a digital wire harness diagram. At least one wire harness assembly station may move along a first track, and a test adapter associated with the electrical testing unit may be movable along a second track. The at least one computing device may execute a test program at the wire harness assembly station while the wire harness assembly and the test adapter move, respectively, along the first and second tracks.

### CROSS REFERENCE TO RELATED APPLICATIONS

This application claims benefit under 35 U.S.C. § 119(e) of Provisional U.S. Patent Application No. 63/598,202, filed Nov. 13, 2023, the contents of which is incorporated herein by reference in its entirety.

### TECHNICAL FIELD

The present disclosure relates to wire harnesses, and more particularly to wire harness assembly and testing.

### BACKGROUND

Wire harnesses include structured arrangements of electrical wires, cables, connectors, and components to efficiently transmit electrical signals within a system or device. Wire harness assembly often involves labor-intensive, manual routing of numerous electrical components according to a wire harness diagram. However, manual routing is time consuming and susceptible to human error and inefficiencies.

Assembled wire harnesses typically undergo electrical testing to ensure that the assemblies are functional and properly connected before any integration into an intended system or device. Wire harness testing conventionally requires visual inspection and manual checks to verify electrical connectivity of individual wires. Different wire harness designs often require unique testing protocols due, for example, to differing components, harness lengths, and other electrical requirements. But due to the manual nature of wire harness assembly, speed, efficiency, and accuracy remain limited.

### SUMMARY

In accordance with an aspect of the present disclosure, there is provided systems and methods for automated wire harness assembly and testing. Aspects include wire harness assembly systems, automated testing methods, and related features.

A wire harness assembly system may include, a display providing information associated with a digital wire harness diagram, a screen positioned in front of the display, a mount to secure a cable connector in front of the display, an electrical testing unit for verifying electrical connections on a wire harness assembly, and a computing device comprising a processor and a memory. The cable connector mount may include a base section having a rear protrusion to attach to the screen, and a top protrusion to secure the cable connector. The base section may be rotatable around a point of attachment with the screen, and the top protrusion may be movable to adjust a lateral position relative to the base section. The computing device may generate, on the display, the information associated with the digital wire harness diagram, establish a connection between a test adapter associated with the electrical testing unit and a test point for a set of cables connected via the cable connector, and execute, by the electrical testing unit, a test program associated with the digital wire harness diagram.

A wire harness testing system may include a first track defining an area for assembling wire harnesses, a motor connected to a frame supporting a wire harness assembly, a second track defining a travel path for a test adapter, wherein the test adapter is associated with an electrical testing unit for verifying electrical connections, and a computing device comprising a processor and a memory. The motor may be configured to move the frame along the first track, and the wire harness assembly may include a cable connector electrically connected to a set of cables, and a test point associated with the set of cables. The computing device may connect the test adapter and the test point, execute, by the electrical testing unit, a test program associated with the wire harness assembly, and disconnect the test adapter and the test point.

A method for manufacturing a wire harness may include: generating, using at least one design software, a cable connector based on a digital wire harness diagram, and a program to test electrical connections of a set of cables to be joined by the cable connector, producing the at least one cable connector using an additive manufacturing process, assembling the wire harness at an assembly station, establishing a connection between a test adapter associated with an electrical testing unit and the test point associated with the set of cables, executing, by the electrical testing unit, the program associated with the digital wire harness diagram, and generating output indicative of a result of the program. The wire harness may include the cable connector, the set of cables, and a test point associated with the set of cables. The assembly station comprises a display providing the digital wire harness diagram, a screen positioned in front of the display, and a mount to secure the at least one cable connector to the screen.

Wire harness testing systems and methods may also include a wire harness assembly supported by a frame connected to a motor, wherein the motor moves the frame along a first track, a test adapter movable along a second track, wherein the test adapter is associated with an electrical testing unit to test electrical connections, and a computing device comprising a processor and a memory comprising instructions configured to cause the computing device to: execute a test program while the wire harness assembly and the test adapter move, respectively, along the first track and the second track.

These and other features will be more clearly understood from the following detailed description taken in conjunction with the accompanying drawings and claims. This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present disclosure will be described more fully hereinafter with reference to the accompanying drawings, in which:

FIG. 1 illustrates an example wire harness assembly station.

FIG. 2 illustrates an example display associated with a wire harness assembly station.

FIG. 3 illustrates an example digital wire harness diagram.

FIG. 4 illustrates an assembly screen for wire harnesses.

FIG. 5A illustrates a top view of an attachment component.

FIG. 5B illustrates an alternate view of an attachment component.

FIG. 5C illustrates a side view of an attachment component.

FIG. 5D illustrates a bottom view of an attachment component.

FIG. 6 illustrates an example design for a cable connector.

FIG. 7 illustrates another example of a cable connector.

FIG. 8 illustrates a digital, cross-sectional rendering of a cable connector.

FIG. 9 illustrates a wire harness assembly process.

FIG. 10 illustrates aspects of a wire harness testing process.

FIG. 11 illustrates an automated testing system.

FIG. 12 illustrates a movable testing unit and features associated with the automated testing system.

FIG. 13A illustrates aspects of the automated testing process.

FIG. 13B illustrates aspects of the automated testing process.

FIG. 14 is an illustration of an example block diagram of a general-purpose computer system.

### DETAILED DESCRIPTION OF ILLUSTRATIVE EMBODIMENTS

The present disclosure relates to systems and methods for wire harness assembly and testing. Aspects of the present disclosure utilize digital wire harness diagrams, ergonomic assembly stations, and automated electrical testing systems and methods to provide significant improvements to the traditionally labor-intensive manufacturing process. A digital harness diagram may, for example, be provided at a particular assembly station, provide a blueprint for custom-cable connectors, and initiate an automated assembly process. A movable electrical testing unit may connect to and test electrical connections of wire harnesses assemblies as wire harness assembly stations move about an area (e.g., a manufacturing floor, an assembly space, etc.). In some examples, a conveyor system may connect to and move a plurality of assembly stations, while a movable testing unit test electrical connections of assembled wire harnesses.

Such embodiments and features may provide a continuous and improved rate of production through the design of an individual wire harness assembly station, and mobility advantages provided by the conveyor system and enhanced electrical testing processes. Assembly stations provide improved designs with space for an assembler to view the wire harness assembly diagram, identify and obtain wire harness components, easily attach components to an assembly screen in front of the wire harness diagram, and electrically test assemblies. The conveyor system may also reduce physical labor and movement of the assemblers, by cycling a plurality of assembly stations along a path and automating the testing method. In some examples, assembly tasks may be segmented along a plurality of positions (e.g., along a path of the wire harness assembly station), such that a repeated task (e.g., providing cable connector and mounts in the proper positions, connecting wires, labeling harnesses, etc.) may be performed at a given position. Divided tasks and movement of wire harness assembly stations along a path may reduce a number of tasks to be performed by an assembler and reduce errors.

Manufacturing space requirements may also be improved, since assembly stations and movement paths may be customized and easily moved within a particular area, while providing efficiencies at each individual assembly station. Such improvements may result in lower manufacturing cycle times, error reduction, and assembly speed improvements.

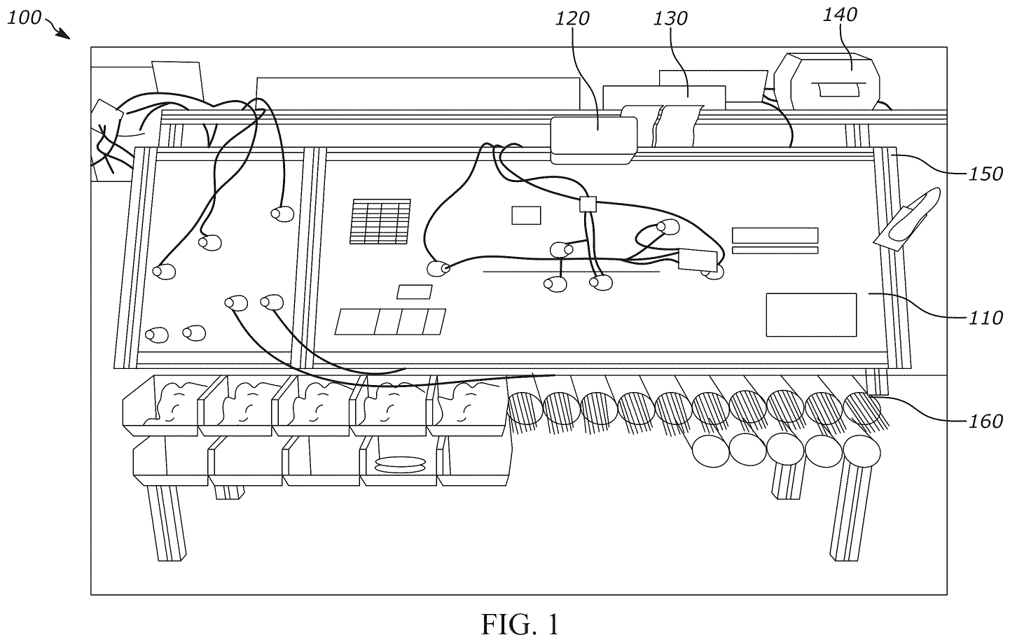

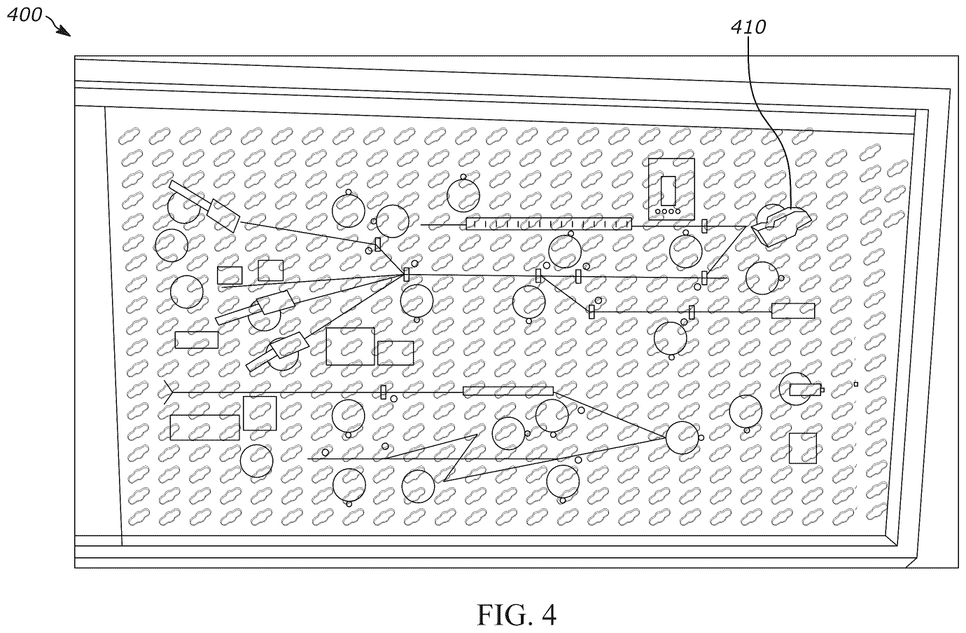

FIG. 1 illustrates an assembly station 100 for preparing a wire harness. The assembly station may include a display 110 providing a digital wiring diagram, a computing device 120, a testing unit 130, a printer 140, an adjustable frame 150 secured to the display 110 and a screen (see, e.g., FIG. 4, assembly screen 400), and at least one storage container 160 for storing wire harness components. The assembly station may provide an efficient, ergonomic design to expedite the assembly process. Wire harness assembly components may, for example, be positioned in one or more storage containers 160 on or around the frame, within a reachable distance, to increase a speed at which an assembler may prepare the wire harness assemble and reduce unnecessary movements. Wire harness assemblies may include small to mid-size harnesses (e.g., 6 to 46 circuits), and larger assembly sizes.

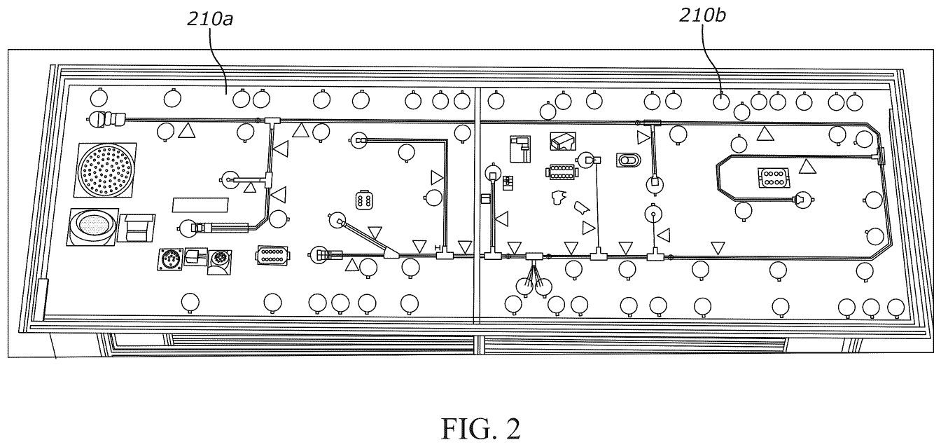

The display 110 may include one or more monitors, televisions, digital screens, and other display devices for providing a digital wiring diagram. The digital wiring diagram may project a one-to-one scale representation of a wire harness. The display size, e.g., a screen size, may be selected to enable the scale representation of the wire harness. Any of a combination of display sizes, types, and models, may be used to provide the digital wiring diagram. In some examples, the display may include a 50″, 55″, 60″, 65″, 70″, 75″ screen. In other examples, as illustrated in FIG. 2, two or more displays may provide the digital wiring diagram. The size of the display may be selected to correspond to a size of the wire harness diagram. For example, one or more screens may be selected to enable a one-to-one scale image of the wire harness to be provided.

The computing device 120 may manage the digital display and various testing aspects associated with the assembly station 100. The computing device 120 may include a processor connected to elements of the assembly station 100, including but not limited to the testing unit 130, printer 140, and display 110. The computing device 120 may further connect (e.g., locally, remotely, etc.), via a network (e.g., a wired network, wireless network, cloud network, etc.), to at least one remote computing device, database, server, or system.

The computing device 120 may be configured to generate and present visual content, such as the digital wiring diagram to the display 110. In some examples the computing device may communicate with a user interface module to allow user selection and interaction with the displayed visual content. For example, the user interface module may be usable with the computing device 120 to select a digital wiring diagram to be displayed, and to adjust various display parameters, including but not limited to diagram scale, sizing, brightness, color, and resolution.

As discussed herein, the digital wiring diagram may provide a blueprint for the wiring assembly, identifying various electrical components, wiring configurations, and sizing for a particular wire harness. The digital wiring diagram may also provide placement and connectivity information to aid with assembly. Wire harness components and connections may be assembled on a surface or a screen positioned directly in front of the displayed digital wiring diagram.

The assembly station 100 may improve assembly speed and efficiency through one or more modifiable features, which enable users to customize the assembly station to their preferences and needs. For example, the frame 150 may be adjustable around a horizontal axis, thereby enabling a user to tilt the display and customize its angle to a desired position. The vertical position of the frame may similarly be adjusted to accommodate various user heights and preferences.

In some examples, the frame 150 may hold the display 110, and be adjustable to accommodate various sizes and types of displays. An assembly screen for wiring components may also attach to the frame. Frame movement 150 may cause concurrent, synchronized movements of the display 110 and assembly screen, so that any components of the wire harness assembly remain similarly positioned over the displayed digital wire harness diagram.

One or more types of storage containers 160 may be positioned on or around the frame. Containers may hold various wire harness components, such as wires, connectors, clips, and other attachments and electrical devices. FIG. 1 illustrates a plurality of containers 160 positioned beneath the display 110. However, storage containers 160 may be positioned at any desired location on or around the frame, for example, in one or more positions that are easily accessible or reachable for the user. Similar to other assembly station components, the container positions may be modifiable. The storage containers 160 may be moved, removed, adjusted, angled, or otherwise positioned as desired within the assembly station workspace.

The testing unit 130 performs electrical testing associated with assembled wire harnesses. Wire harness designs may require different electrical tests, due to different designs, electrical, components, and intended functions. As such, testing unit 130 may include any of a plurality of electrical components to test the integrity and functionality of the prepared electrical wire harness and cables. For example, the testing unit 130 may include one or more connectors or terminals through which the wire harness wires and cables may connect. Some testing units may include a user interface on which a user may initiate tests, select parameters and view results.

In some examples, the testing unit 130 may communicate with computing device 120 to download a test and its specific parameters for a wire harness, such as a wire harness associated with a displayed digital wiring diagram. The testing unit 130 may also include a processor and memory containing executable software for various testing processes and parameters.

Testing units 130 may further include a voltage source and/or signal generator to test specific signals, functions, and/or real-world conditions. Other electrical testing components may include but are not limited to a multimeter (e.g., for testing voltage, current, resistance, etc.), a continuity tester, and insulation and resistances testers. The testing unit 130 may also include one or more displays and indicators to output test results, diagnostic information, and other information associated with the electrical tests. For example, a display on the testing unit 130 may display “PASS” or “FAIL” results.

A printer 140 connected to the testing unit 140 may also provide an output source for test results. The printer 140 may be connected to the computing device 120 and usable to print out information regarding the wire harness assembly, such as labeling, barcodes, and QR codes, which may be secured to the wire harness assembly. Some aspects may also include a scanner connected to the computing device 120. The scanner may be usable to share and identify information related to wire harness assembly.

FIG. 2 illustrates an example of a wire harness assembly station including a first display 210a and a second display 210b displaying a digital wire harness diagram. Digital wire harness diagrams may be displayed at a one-to-one scale of its intended size, to simplify assembly, increase efficiency, and minimize measurement errors. Various screen sizes and types may be used, alone or in combination, to accommodate different wire harness assemblies and designs. Some wire harness assembly stations may include two displays (e.g., 55″, 60″, 70″ 75″, etc.). Other display arrangements may be selected to accommodate a certain size, such as a 3′×6′ assembly area. A wire harness assembly may require a larger assembly area, and therefore require a larger display and/or additional displays.

The computing device 120 may therefore be configured to adjust the display of a digital wiring diagram depending on available displays, such as a number or type of connected displays. The computing device 120 may adjust various aspects of the display, including a sizing and position of the digital wiring diagram, to present the digital wiring diagram in an efficient manner on available displays.

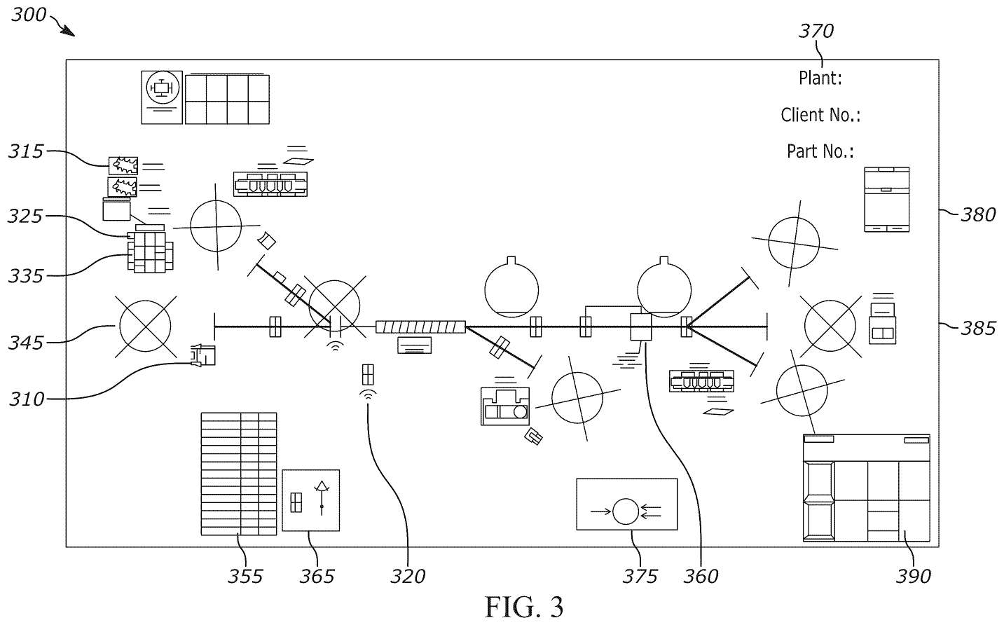

FIG. 3 illustrates an example wire harness diagram 300. The wire harness diagram 300 may be provided on a display (e.g., display 110), as discussed herein. The wire harness diagram may be provided within a digital frame 385, which may correspond to a display frame (e.g., frame 150). The wire harness diagram may include symbols, images, and information for assembling a particular wire harness, including specific parts, positions, and placements for assembly. A displayed digital wire harness diagram may provide a one-to-one scale version. A user may place particular wire harness components in front of a displayed position on the wire harness diagram and assemble the wire harness by following the diagram and its displayed instructions.

In various examples, the diagram 300 may include symbols, images, videos, and/or audio information indicating part types, placements, and positions. FIG. 3 illustrates a symbol and associated positions for wire harness components, including a connector 310, a cable tie 320, spot tape 330, a wrap 340, a distance between spot tape 350, and labels 360. The diagram 300 may also provide information about specific parts and components in the wire harness assembly. For example, the diagram 300 may provide at least one of an image of a particular part (e.g., connector lock 315), visual aids 325 (e.g., circuits and insertion positions), a circuit identification 335, cable holder information 345, a circuit listing 355, part quantities 365 (e.g., cable tie and spot tape quantities), and symbology 375 (e.g., splice symbology). The diagram 300 may further include information regarding the wire harness itself, such as a type of wire harness (e.g., a part number or associated client number 370), designer information 380, and harness packing information 390.

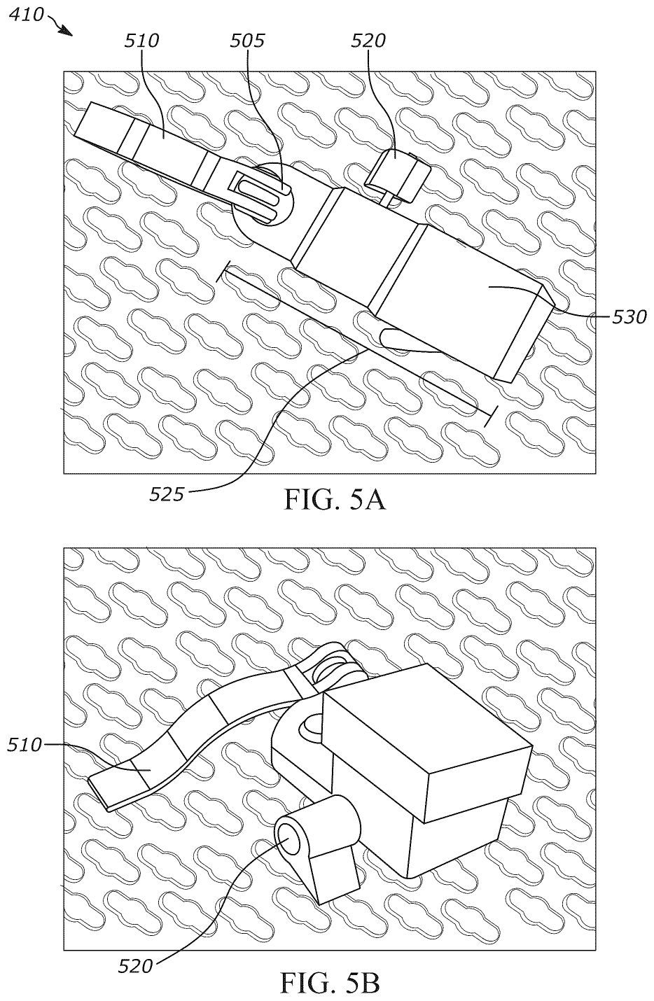

FIG. 4 illustrates an assembly screen 400 on which a wire harness may be assembled. The assembly screen 400 may provide an assembly screen for various connectors and wire assembly components (see, e.g., FIGS. 5-8). In some examples, the assembly screen may include a plurality of holes to support the attachment of one or more wire assembly components. As illustrated in FIG. 4, the assembly screen 400 may be positioned in front of a display providing a digital wire harness diagram and enable wire assembly components to be placed directly in front of the corresponding component illustrated on the wire harness diagram. The assembly screen 400 may be attached, for example, to a frame (e.g., frame 150) connected to at least one of a display (e.g., display 110) and a conveyor system, as discussed herein.

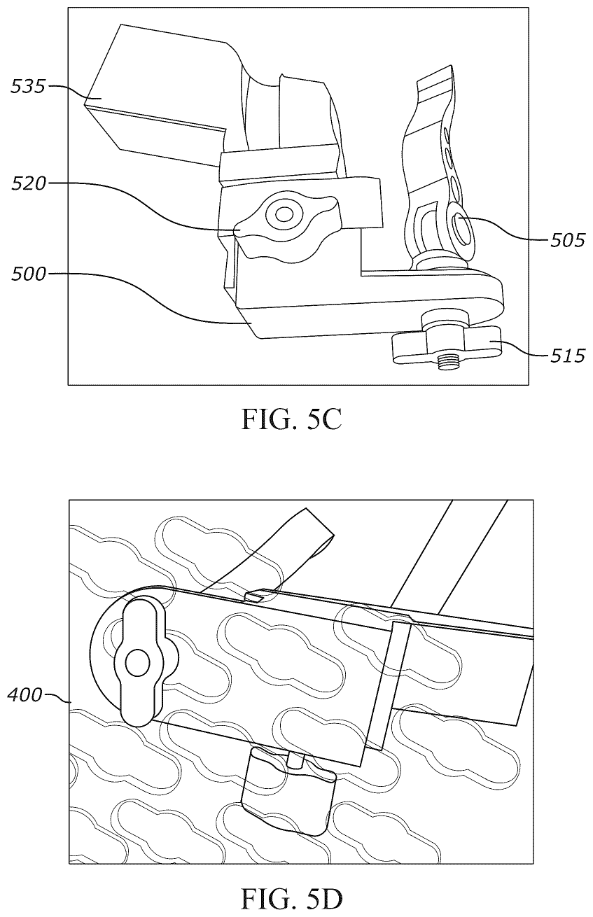

In some examples, the assembly screen 400 includes a plurality of evenly spaced, and similarly shaped holes configured to receive a corresponding attachment component 410 (also referred herein as a “mount”). The attachment component 410 may be secured to a cable holder (e.g., cable holder 535 as shown in FIG. 5C) or a cable connector (e.g., cable connector 600 as shown in FIG. 6)). The attachment component 410 therefore may attach to any of a plurality of positions on the assembly screen 400 for precise positioning.

In some examples, the assembly screen 400 may be formed from a transparent material, such as a clear plastic, plexiglass, or other polymer or composite material. In other examples, the assembly screen allows a wiring diagram positioned behind the assembly screen to be viewed through holes, openings, or other means.

FIGS. 5A-5B illustrate top and perspective views of an example attachment component 410. FIGS. 5C-5D illustrate side and bottom views of the example attachment component 410. The attachment component 410 may include base section 500 that includes a rear protrusion 515 that is shaped to fit into a hole or other opening on an assembly screen 400. The rear protrusion 515 may be rotatable, and positioned opposite the point of attachment 505. In some examples, as seen in FIG. 5D, the protrusion attaches to the assembly screen 400 due to its specific shape, is designed to fit into a corresponding hole, and may include a hook feature to secure positioning within a hole.

The attachment component 410 further includes positioning features to fine tune its placement on the assembly screen 400. For example, the attachment component 410 may be rotatable around a longitudinal axis extending from the point of attachment 505 on the assembly screen 400. A first lever 510 may tighten the attachment component 410 to the assembly screen and prevent further movement or rotation about point 505 once the attachment component is in its desired position. In an example, rotation of the first lever 510 adjusts a rotation of the rear protrusion 515. This may allow the rear protrusion 515 to be oriented relative to a hole in the assembly screen 400 to secure its placement. The first lever 510 may also serve as a clamp to tighten the rear protrusion 515 and the base section 500 against opposite sides of the assembly screen to prevent movement, once the attachment component 400 is in a desired position and orientation.

A second lever 520 may adjust a lateral position of the attachment component 410, for example, along a length 525 of the base section 500. The attachment component 410 may include a top protrusion 530 for securing a cable holder 535 or a cable connector (see, e.g., FIGS. 6-8). Adjusting the mount position may be beneficial for proper cable and component positioning during assembly.

In some examples, the attachment component 410 includes base section 500 having an additional rear protrusion for attachment to an assembly screen 400 or other surface. A protrusion on an opposite side (e.g., a top protrusion) may be attachable to the cable holder 535 or other component of a wire harness assembly. In some examples the top protrusion may attach to a corresponding-shaped base of the cable connector, such as a snap fit. In other examples, the top protrusion may secure to the cable connector via one or more levers and tightening mechanisms.

Although FIGS. 5A-5D illustrate an attachment component with two levers, more or less positioning components may be provided to refine a position of the attachment component on an assembly screen.

The attachment component 410 may be formed using an additive manufacturing process, such as 3D printing. One or more parts of the attachment component (e.g., base section 500, protrusions 515, 530, and levers 510, 520) may be customized, using 3D drawing software, and printed to a desired size and shape, so that the attachment component 410 can be used with various assembly board, wire harness, cable holder, and cable connector designs. The attachment component 410 may be printed as a singular component or in separate parts that may be fit together to form the attachment component.

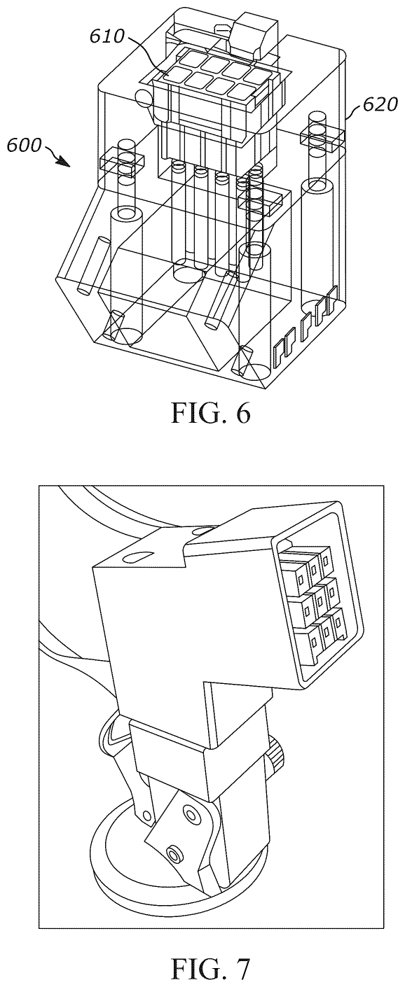

FIGS. 6-7 illustrate a cable connector 600, which may be secured to an attachment component 410. Cable connectors are a fundamental element of wire harnesses and provide a receptacle for securing and electrically connecting one or more wires and cables. FIG. 6 illustrates a transparent computer-aided design (CAD) rendering of the cable connector illustrated in FIG. 7. According to various examples, a cable connector may be partially or fully designed using a CAD program. Cable connectors may include a connector body 610, which forms a protective housing or outer shell around the internal components. The body 610 may be designed to a certain shape or size, depending, for example, on the number or types of wires and cables, its intended application, or other practical or aesthetic considerations. A cable connector 600 also may include one or more contacts or pins 620 providing a point of electrical contact for connected wires. Optionally, other features may include strain relief and/or sealing mechanisms, gaskets, clamps, grommets, labels, cable identification features, shielding or grounding features, and protective features, such as dust caps, covers, and seals.

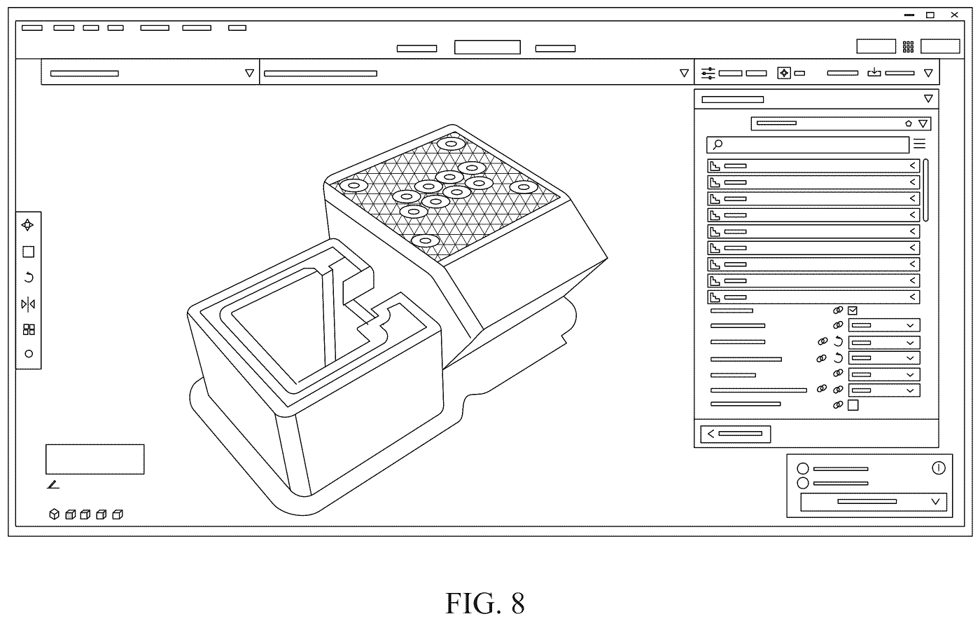

As shown in FIG. 8, cable connectors designs may include three-dimensional (3D) CAD drawings defining the cable connector's physical dimensions, components, and/or electrical connections. As such, cable connectors may be efficiently customized to particular specifications and requirements, including but not limited to a type of a connector, a number of pins or contacts, materials, insulators, insertion points, locking mechanisms, and other electrical features. Other design aspects may be defined, such as an overall shape, size, orientation, and spacing.

According to some examples, the cable connector design may be provided to a secondary software for manufacturing (e.g., additive manufacturing). In some examples the secondary software may be a 3D printing software (e.g., GCODE), and the manufacturing method may be performed using one or more 3D printers. In various examples, a first design software (e.g., SOLIDWORKS, AUTOCAD, etc.) may generate the cable connector design, and a second software, (e.g., 3D printing software) may generate the instructions for a 3D printer to print the cable connector.

The base sections 500 of attachment components 410 may be designed, manufactured (e.g., 3D printed), assembled to include any protrusions, levers or positioning components, and used to assemble wire harnesses in much the same manner as cable connectors. Accordingly, for each unique component of the wire harness to be assembled, there may be a correspondingly unique base section and attachment component to be designed, manufactured and used.

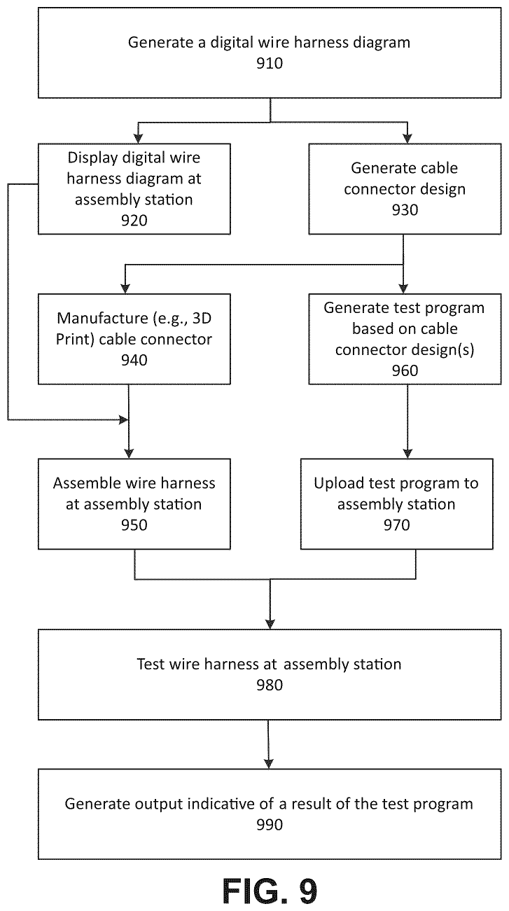

FIG. 9 illustrates an example process for assembling and testing a wire harness. The process may be performed using a wire harness assembly station, as described herein. At block 910, aspects may generate a digital wire harness diagram (see, e.g., FIG. 3). The digital wire harness diagram may be generated using one or more computer programs, defining wire harness components, electrical connections, connection points, and other features. The digital wire harness diagram may include sizing and scaling information, so as to provide a one-to-one scale image to one or more displays associated with the wire harness assembly station. In some examples, the digital wire harness diagram may be generated manually and/or automatically, using 2D or 3D design software. Such design software may particularly define electrical connections, wire types, cable lengths, attachment parts, labels, ties, barcodes, product numbers, electrical layers, cable connector requirements, and the like.

At block 920, aspects may display the digital wire harness diagram at the assembly station. As discussed herein, the digital wire harness diagram may provide a blueprint or visual aid for assembly via the display associated with the assembly station. The diagram may scale automatically, for example, according to a size of the display, such as the screen size. In some examples, the digital wire harness diagram may be provided to a computing device (e.g., computing device 120) associated with the assembly station. The computing device may then scale and render the diagram on one or more displays.

At block 930, the digital wire harness diagram may be used to generate a cable connector design, which may be provided as a digital design. As noted herein, the cable connector may provide a receptacle to secure, combine, and/or electrically connect one or more wires. Cable connectors may be designed using a CAD program defining one or more electrical features, terminals, a shape, a size, colors, parts, electrical requirements, and various components. The cable connector may also be designed to conform to particular assembly station features, such attachment component (e.g., attachment component 410), to aid with physical and/or manual assembly of the wire harness. While reference in FIG. 9 is to generating the cable connection design and manufacturing the cable connector, it should be understood that the same steps may equally apply to designing and manufacturing one or more portions of the attachment component 410, including the base section 500, protrusions 515, 530, and levers 510, 520.

At block 940, aspects may manufacture the cable connector. Manufacturing may include additive manufacturing processes, such as those utilized in 3D printing. In some examples, one or more files associated with cable connector design may automatically be provided to a 3D printer for printing. Such techniques may significantly expedite the wire harness assembly process, as the cable connector design may be provided to a plurality of 3D printers or other manufacturing devices to manufacture a plurality of cable connectors. The manufacturing device may be an automated, computer-aided process, as in 3D printing.

According to various examples, attachment components, cable holders, cable connectors, and particularly, 3D-printed cable connectors may be formed using any of a plurality of materials usable in additive manufacturing processes. Such materials may include but are not limited to thermoplastics, nylon, polycarbonates, polypropylene, resins, photopolymers, and composite materials. Any of a combination of materials may be used to generate a cable connector with desired properties with respect to strength, flexibility, durability, and heat resistance, for example.

At block 950, aspects may include assembling the wire harness at an assembly station, as described herein. The wire harness may be assembled in front of a displayed digital wire harness diagram. Electrical components for the wire harness may be provided on or near a working area associated with the assembly station. As described herein, the wire harness assembly may be secured to an assembly screen positioned in front of the wire harness diagram.

At block 960, aspects may generate a test program based on the cable connector design(s). As discussed herein, wire harness tests provide quality control and verification mechanisms to determine that a wire harness meets specified electrical, mechanical, and safety requirements. Test programs may verify electrical connections and features associated with one or more aspects of the wire harness assembly.

In some examples, a test program may be automatically generated based on the digital wire harness diagram. Electrical components, connections, and features defined in the digital wire harness diagram may be assessed, e.g., manually and/or computationally, to determine expected electrical and compliance criteria. Wire harness test programs may, for example, include test related to continuity, resistance, insulation, dielectric strength, circuit integrity, and environmental testing. In some examples, software may define a plurality of relation points associated with the wire harness assembly, and the test program may specify particular tests and acceptable test results associated with the relation points.

At block 970, test programs may be implemented with a testing unit, as discussed herein. In various examples, a test program may be generated based on the digital wire harness diagram and/or the particular cables and electrical components of the wire harness design. The test program may specify particular compliance requirements to be associated with the wire harness assembly. In some examples, the test program is automatically generated from at least one of the digital wire harness diagram, and the cable connector designs. In various examples, the test program may define a series of tests to be performed on an assembled wire harness.

The test program may be provided to a testing unit associated with a wire harness assembly station. For example, the test program may be provided to computing device 120, which may operate or otherwise communicate with the testing unit 130.

At block 980, aspects may test the wire harness, in accordance with the test program, at the assembly station. The test program may be operated upon completion of the wire harness assembly. A verification, such as a label scan, or other check may be required to confirm a wire harness assembly design and its associated test program. Other verification and/or safety mechanisms may be implemented to ensure that an assembled wire harness is tested with the correct test programs, and that the tests are performed in compliance with any safety requirements.

At block 990, aspects may generate output indicative of a result of the test program. The result (e.g., indicating a pass or fail) may be provided on at least one of: the electrical testing unit, the display, and a peripheral device. In some examples, a connected printer may print the results. The result may include a notification, such as a visual or audio notification, and may be provided to one or more local or remote computing devices.

In an example, in accordance with FIG. 9, a wire harness assembly may include preparation and operation processes. Preparation processes may be associated with the design and initial assembly steps associated with a wire harness, whereas operation processes may be associated with the component assembly and electrical testing.

In the example, a digital wire harness diagram may be generated using 2D design software. The 2D design software may allow selections of particular wire harness components, custom grouping, and flexible design of a wire harness assembly. The 2D design may then generate an image file usable to provide a one-to-one scale for assembly. The one-to-one scaled image may be provided on one or more display associated with a wire harness assembly station.

Preparation processes may further include generating cable connector and holder designs using 3D design software. In some examples, the cable connectors, including one or more terminals, electrical components, and other features may be automatically generated from the 2D design, and based, at least in part, on the components provided in the 2D design. In other examples, cable connectors may be manually modified to conform to one or more design preferences or requirements.

3D design files associated with cable connectors may be provided to a 3D printing software, to provide and refine manufacturing information associated with the cable connector design. In some examples, multiple layers may be examined, edited, and defined, as desired. Materials may also be specified. Once the cable connector design is finalized, it may be provided to one or more 3D printers for manufacturing. Such additive manufacturing methods may provide significant improvements with respect to consistency and production efficiency. Such additive manufacturing methods may enable cable connectors to be designed and created in-house, thereby eliminating associated shipping time and costs associated with third parties. Such processes may also be automated to efficiently product cable connectors and wire harness components, as needed. Base sections of attachment components may be processed in the same manner.

Such cable connectors may be secured to an attachment component, as discussed herein, to provide precise and efficient positioning of one or more cables and cable components. An electrical test program may also be generated using programming software. The test program may be automatically and/or manually generated based on at least one of the digital wire harness diagram and cable connectors. The test program may be uploaded to a testing unit associated with the assembly station, and provide one or more electrical tests, such as a test sequence, to an assembled wire harness.

Operation processes may begin at an assembly station, upon receipt of a work order with a part number and a quantity of wire harnesses to be produced. In some examples, the digital wire harness diagram may be automatically provided to a display associated with the wire harness station via computing device 120. The digital wire harness may be provided after an action taken at the wire harness assembly station, such as scanning a barcode, label, or QR code associated with a work order or wire harness.

In some examples the associated test program must be selected, for example, at the testing unit. The testing unit may include one or more buttons, displays, indicators, or other means for making a selection. In some examples, the testing unit automatically selects the corresponding test program based on a displayed wire harness, or other information provided at or by a connected computing device.

Wire harness assembly may be performed, based on a displayed digital wire harness diagram. The physical components associated with the wire harness may be mounted to the assembly screen, and one or more cable connectors may be attached, as described herein. Cable ties, labels, and other features may be assembled, as needed, or as directed by the wire harness diagram.

Once assembled, the wire harness assembly may undergo testing based on the uploaded test program. In some examples, a bar code associated with the wire harness assembly may need to be scanned to verify that the present wire harness layout matches with the current work order. In some examples, the test program may include a series of electrical tests. The test program may iterate through its defined tests, indicating one or more current wires and/or cable connectors to connect and test, then indicating a next set of components to test.

The testing unit and/or display may provide visual aids during the testing process. For example, the display may indicate a particular wire or harness component to test. The testing unit may provide “PASS” or “FAIL” indications, using a display, lights, colors, LED indicators, sounds, and the like.

In some examples, additional safety mechanisms may be implemented during wire harness assembly and testing. A cable lock may be provided on a grouping of wires during assembly. If the wire harness passes the test program, the cable lock may be opened, e.g., to allow the wire harness to be removed. Otherwise, the wire harness remains locked in position to prevent a faulty wire harness from being sent to a next stage of manufacturing or delivery. One or more labels, tags, and ties may be provided at one or more positions along the harness. Such labels may provide information about the wire harness, such as a part number, design number, or electrical information. A printer associated with the assembly station may print informational labels.

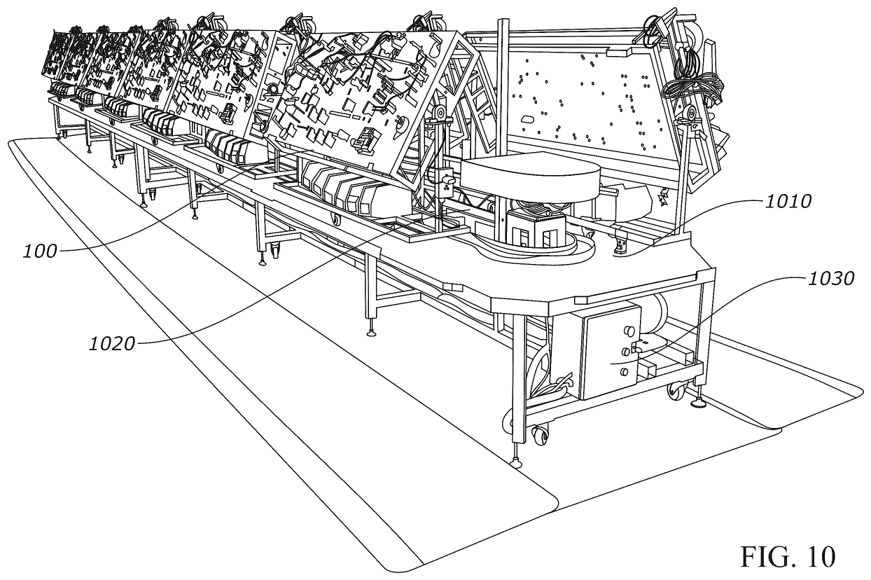

FIGS. 10-13 illustrate automated testing systems and processes. Automated testing systems may include at least one wire harness assembly station, a conveyor system, and a movable testing unit to conduct automated wire harness tests during a movement of a wire harness assembly from a first position to a second position.

An automated testing system including movable wire harness assembly stations and movable testing units may provide significant improvements and assembly efficiencies. For example, automated testing eliminates a need for an assembler to manually connect a testing unit and perform test programs. The mobile design significantly reduces movement by the assembler, including a need for assemblers to move to a new assembly station when a wire harness is assembled. The automated testing system may further promote efficient assembly, since an assembler can remain in a same position and perform a same set of tasks associated with a wire harness assembly. In an example, a first assembler at a first position may fasten cable connectors to an assembly screen, and a second assembler at a second position down the line may connect a same set one or more cables, ties, and labels to the cable connectors fastened by the first person. The automated testing system may therefore enable assembly tasks to be divided and performed at various positions along the length of the first track. Task division can improve assembly speed and reduce errors, since assemblers perform only a subset of the tasks, rather than the entire assembly. The adjustable moving speed of the automated testing system may also help improve, predict, promote, and standardize a rate of production.

FIGS. 10-13 illustrate an automated testing system for wire harness assembly. The automated testing system 1100 (also referred to herein as a “testing unit”) may include a plurality of wire harness assembly stations (e.g., assembly station 100), a conveyor system, and a movable testing unit.

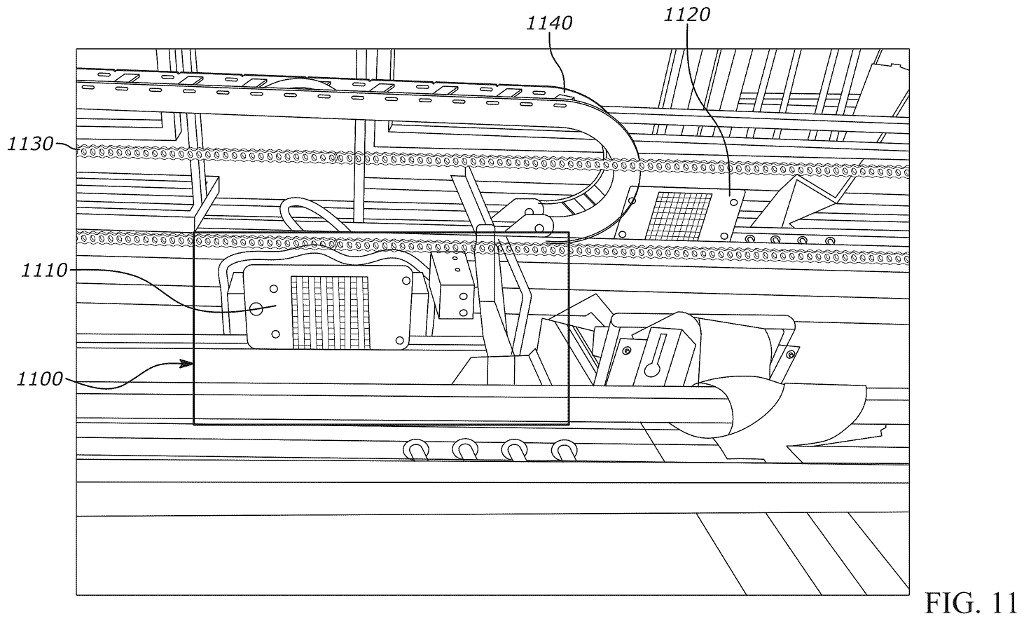

The automated testing system 1000 may move a plurality of wire harness assembly stations (e.g., assembly station 100), and execute a test program via a movable testing unit (e.g., testing unit 1100 of FIG. 11). In an example, the plurality of assembly stations may move along a first track 1010, and the movable testing unit 1100 may move along a second track 1020. The first track 1010 may form a loop, and the wire harness assembly stations may be driven around a central point, in a circular, elliptical, or otherwise rounded path. The second track 1020 may provide a path for the movable testing unit. In some examples, the second track 1020 is provided on an interior portion of the first path, for example, along a length of the elliptical path. The second track 1020 may be a linear track, and the movable testing unit may be positioned behind one or more assembly stations, in a position to easily access and connect to a testing receptacle 1120 associated with the assembly station.

At least one motor 1030 may drive movement of the assembly stations and the movable testing unit. The at least one motor 1030 may drive movement of the one or more assembly stations. In some examples, a motor may also drive the movable testing unit. The conveyor belt and the movable testing unit may also be driven separately. In some examples, the assembly stations may be driven along the first track 1010 at a first speed. The movable testing unit may be separately moved to a position to execute testing. In some examples, the assembly stations are each attached to a conveyor belt 1130. As the conveyor belt 1130 is driven by motor 1030, the assembly stations move along the first track 1010. In some examples, a set of wheels may be provided on a frame (e.g., frame 150) of each assembly station to promote movement along the first track 1010. One or more guide rails may also be provided to ensure proper movement along the first track.

The movable testing unit 1100 may connect to a retractable arm 1140 that moves along the second track 1020. As noted above, the second track 1020 may be a linear path positioned behind one or more assembly stations. The movable testing unit may include a set of electrical contacts (also referred to herein as a test adapter 1110) to align with a corresponding test point, e.g., on testing receptacle 1120, associated with a wire harness and an assembly station. The test adapter 1110 may connect with the test point on the testing receptacle 1120 to perform a test program.

In an example, starting from a first, initial position, the movable testing unit 1100 matches a speed of the assembly station, aligns with the testing receptacle of the assembly station, attaches to the testing receptacle, and performs the test program. The test program may run while the assembly station and movable testing unit continue to move along their respective paths. Allowing the testing to be completed as the assembly station and movable test unit continue to move on their paths prevents the assembly station from stopping and starting up again after each test. Such stopping can be disruptive to other workers working on the assembly line and can lead to equipment failure that is avoided in everything just keeps moving. After testing completion, the movable testing unit detaches from the testing receptacle and returns to its initial position. In some examples, the retractable arm 1140 may be configured to allow movement of the testing unit along the second track and return the testing unit 1100 to an initial starting position.

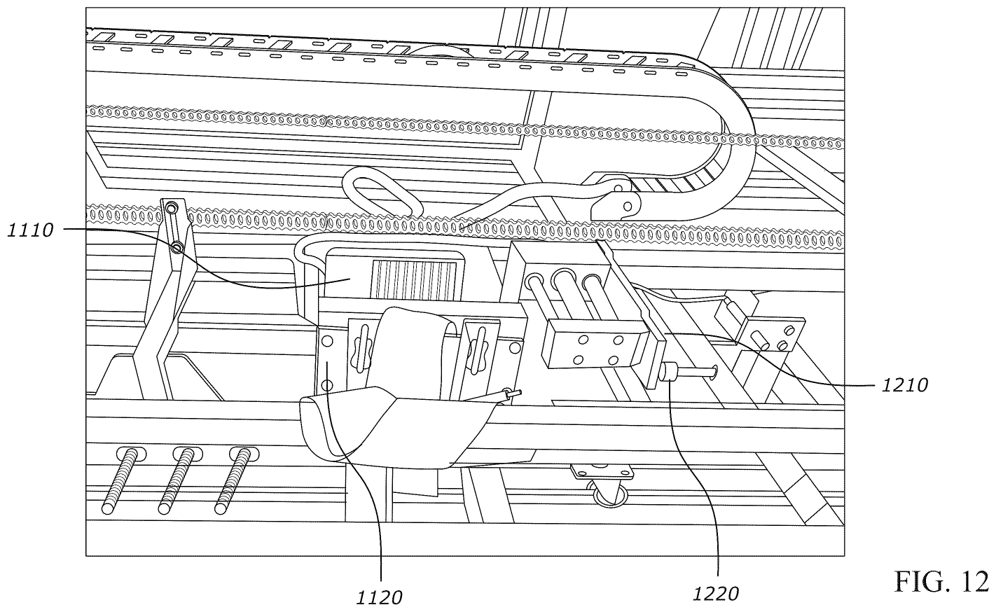

FIG. 12 illustrates an example mechanism for coupling the testing unit 1100 with a test point on the testing receptacle 1120 associated with a wire harness assembly. As discussed herein, a wire harness assembly may include a test point to receive a set of electrical contacts (e.g., test adapter 1110) associated with the movable testing unit.

The movable testing unit may have an extendable plate 1210 that moves between a retracted position (see, e.g., FIG. 11) and extended position (see, e.g., FIG. 12). The plate 1210 may extend when a testing receptacle passes. In another example, the plate 1210 moves to the extended position upon receiving a signal, such as a signal that the testing receptacle has passed or otherwise reached a position. In the extended position, as seen in FIG. 12, a bumper 1220 associated with the assembly station may contact the plate and drive the movable testing unit 1100, including the test adapter 1110, at a same speed as the assembly station being driven by a motor. In some examples, the bumper 1220 is attached to or otherwise formed on frame associated with the assembly station. The bumper may be positioned such that the set of electrical contacts 1110 aligns with the testing receptacle 1120 associated with the assembly station.

Once aligned, and while the movable testing unit is being driven by bumper 1220, the set of electrical contacts 1110 may then extend to connect with the aligned and testing receptacles 1120. The testing unit may perform a test program, as discussed herein. Once testing is completed, the set of electrical contacts 1110 may retract to its initial position, and the plate 1210 may also return to its retracted position.

Once the test point and test adapter disconnect, an arm 1140 connected to the movable testing unit 1100 may return the movable testing unit to the initial position. The testing process may repeat when the testing receptacle of a next assembly unit passes.

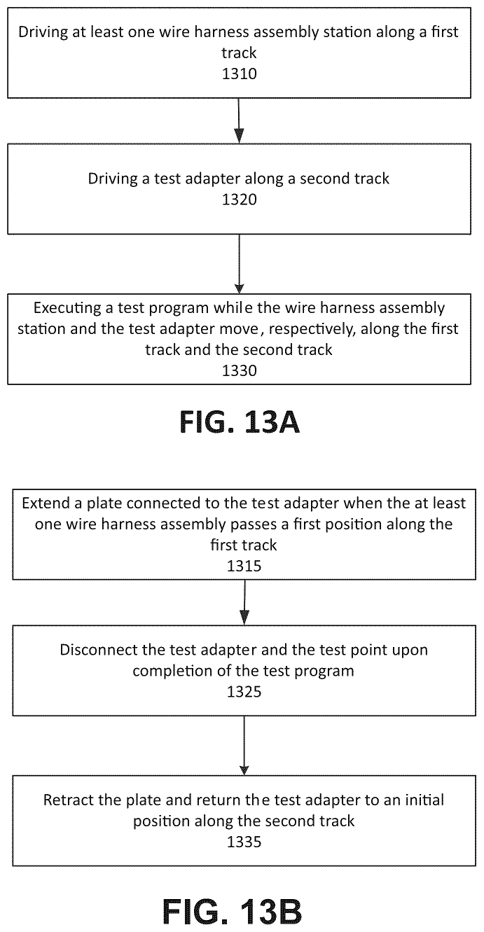

FIG. 13A illustrates an example wire harness testing process, in accordance with embodiments discussed herein. At block 1310, aspects may drive at least one wire harness assembly station along a first track. The first track may, for example, be a path within a room (e.g., a manufacturing floor) or other area in which wire harness assembly occurs. In some examples, the first track is provided on a table. The first track may be a looped path.

At block 1320, aspects may drive a test adapter along a second track. The test adapter may be associated with an electrical testing unit (e.g., testing unit 1100). In some examples, the second track run parallel to the first track for a length. The second track may be positioned near a path of the one or more wire harness assembly stations (e.g., at a position behind the one or more wire harness assembly stations) to enable a connection between a test point associated with the wire harness assembly, and the test adapter.

At block 1330, aspects may execute a test program while the wire harness assembly station and the test adapter move, respectively, along the first track and the second track. As noted above, the wire harness assembly station and the movable testing unit may move at a same speed along their respective tracks during the test program. The wire harness assembly station may contact the test adapter to move the test adapter along the second track, at least, for the duration of the test program.

FIG. 13B illustrates aspects of a wire harness testing process and may be usable with one or more aspects of FIG. 13A. FIG. 13B provides an example process for electrically connecting an electrical test unit and a wire harness assembly.

At block 1315, aspects may extend a plate connected to the test adapter when the at least one wire harness assembly passes a first position along the first track. In some examples, a computing device may determine a position of the wire harness assembly and assist with timing and alignment of the test adapter and the test point.

At block 1325, aspects may disconnect the test adapter and the test point upon a completion of the test program. One or more computing devices may determine a time for disconnection, for example, upon an indication (e.g., from the electrical testing unit) or a test result, completion, or error. In other examples, disconnection may occur when at least one of the wire harness, the wire harness assembly station, and the test point pass a second position along the track.

At block 1335, aspects may retract the plate and return the test adapter to an initial position along the second track. As discussed herein, the test adapter may passively return to the initial position, or be driven (e.g., by a motor) back to the initial position.

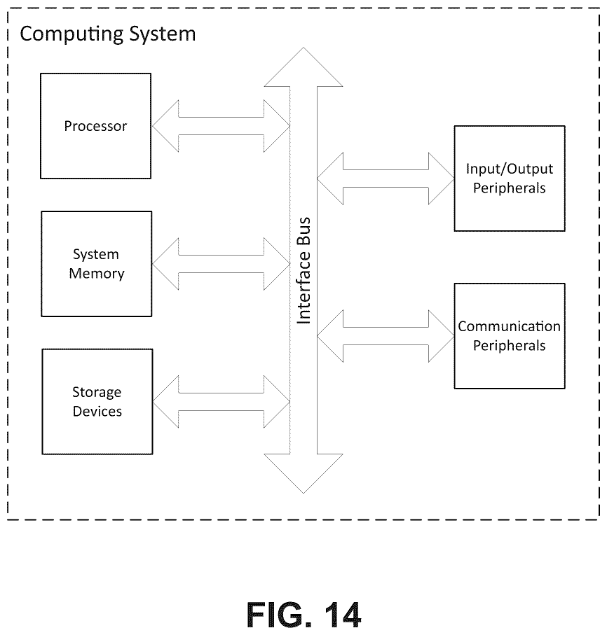

FIG. 14 illustrates an exemplary block diagram of a computing system that includes hardware modules, software module, and a combination thereof and that can be implemented as the computing device and/or as the server. Aspects described herein may be implemented on a computing device associated with one or more wire harness assembly stations, a plurality of computing devices associated with a plurality of wire harness assembly stations, a controller in communication with the wire harness assembly stations) (e.g., a controller configured to manage settings on one or more of the display, the electrical testing unit, a scanner, a printer, etc.), or a plurality of controllers in communication with the wire harness assembly station(s). Additionally, the techniques may be distributed between the computing device(s) and the controller(s).

In a basic configuration, the computing system may include at least a processor, a system memory, a storage device, input/output peripherals, communication peripherals, and an interface bus. Instructions stored in the memory may be executed by the processor to perform a variety of methods and operations, including the digital wire harness diagram preparation and display, managing one or more computer programs associated with the digital wire harness diagram, generating an electrical test program, executing a test program, and performing one or more assembly, manufacturing, and testing processes, as described above. The computing system components may be present in, on, or around one or more wire harness assembly stations, in a server or other component of a network, or distributed between some combinations of such devices.

The interface bus is configured to communicate, transmit, and transfer data, controls, and commands between the various components of the electronic device. The system memory and the storage device comprise computer readable storage media, such as RAM, ROM, EEPROM, hard-drives, CD-ROMs, optical storage devices, magnetic storage devices, flash memory, and other tangible storage media. Any of such computer readable storage medium can be configured to store instructions or program codes embodying aspects of the disclosure. Additionally, the system memory comprises an operation system and applications. The processor is configured to execute the stored instructions and can comprise, for example, a logical processing unit, a microprocessor, a digital signal processor, and the like.

The system memory and the storage device may also comprise computer readable signal media. A computer readable signal medium may include a propagated data signal with computer readable program code embodied therein. Such a propagated signal may take any of variety of forms including, but not limited to, electro-magnetic, optical, or any combination thereof. A computer readable signal medium may be any computer readable medium that is not a computer readable storage medium and that can communicate, propagate, or transport a program for use in connection with the computing system.

Further, the input and output peripherals include user interfaces such as a keyboard, screen, microphone, speaker, other input/output devices, and computing components such as digital-to-analog and analog-to-digital converters, graphical processing units, serial ports, parallel ports, and universal serial bus. The input/output peripherals may also include a variety of sensors, scanners, and the like. The input/output peripherals (e.g., a scanner, a printer, a label maker, a keyboard, a controller, etc.) may be connected to the processor through any of the ports coupled to the interface bus.

The user interfaces can be configured to allow a user of the computing system to interact with the computing system. For example, the computing system may include instructions that, when executed, cause the computing system to generate a user interface and carry out other methods and operations that the user can use to provide input to the computing system and to receive an output from the computing system.

This user interface may be in the form of a graphical user interface that is rendered at a display and that is coupled with audio transmitted on the speaker, images or videos on the display, and microphone and input received at a keyboard, controller, or input device. In an embodiment, the user interface can be locally generated at the computing system. In another embodiment, the user interface may be hosted on a remote computing system and rendered at the computing system. For example, the server may generate the user interface and may transmit information related thereto to the computing device that, in turn, renders the user interface to the user. The computing device may, for example, execute a browser or an application that exposes an application program interface (API) at the server to access the user interface hosted on the server.

Finally, the communication peripherals of the computing system are configured to facilitate communication between the computing system and other computing systems (e.g., between the computing device and the server) over a communications network. The communication peripherals include, for example, a network interface controller, modem, various modulators/demodulators and encoders/decoders, wireless and wired interface cards, antenna, and the like.

The communication network includes a network of any type that is suitable for providing communications between the computing device and the server and may comprise a combination of discrete networks which may use different technologies. For example, the communications network includes a cellular network, a Wi-Fi/broadband network, a local area network (LAN), a wide area network (WAN), a telephony network, a fiber-optic network, or combinations thereof. In an example embodiment, the communication network includes the Internet and any networks adapted to communicate with the Internet. The communications network may be also configured as a means for transmitting data between the computing device and the server.

The techniques described above may be embodied in, and fully or partially automated by, code modules executed by one or more computers or computer processors. The code modules may be stored on any type of non-transitory computer-readable medium or computer storage device, such as hard drives, solid state memory, optical disc, and/or the like. The processes and algorithms may be implemented partially or wholly in application-specific circuitry. The results of the disclosed processes and process steps may be stored, persistently or otherwise, in any type of non-transitory computer storage such as, e.g., volatile, or non-volatile storage.

In an embodiment, a wire harness assembly system, comprises: a display providing information associated with a digital wire harness diagram; a screen positioned in front of the display; a mount to secure a cable connector in front of the display, the mount comprising a base section having a rear protrusion to attach to the screen, and a top protrusion to secure the cable connector, wherein the base section is rotatable around a point of attachment with the screen, and the top protrusion is movable to adjust a lateral position relative to the base section; an electrical testing unit for verifying electrical connections on a wire harness assembly; a computing device comprising a processor and a memory comprising instructions, which when executed by the processor, cause the computing device to: generate, on the display, the information associated with the digital wire harness diagram; establish a connection between a test adapter associated with the electrical testing unit and a test point for a set of cables connected via the cable connector; and execute, by the electrical testing unit, a test program associated with the digital wire harness diagram.

In an embodiment, further comprising: a frame securing the display and the screen; and a conveyor system comprising a motor configured to move the frame between a first position to a second position, wherein the electrical testing unit executes the test program during a movement of the frame between the first position and the second position.

In an embodiment, wherein the test adapter is movable along a track, wherein the test adapter moves concurrently with the frame maintain the connection with the test point during execution of the test program, and wherein the test adapter returns to an initial position on the track after completion of the test program.

In an embodiment, wherein the track is positioned behind the frame.

In an embodiment, wherein the frame comprises a bumper, and wherein the computing device is further configured to: when the frame passes the first position, extend a plate connected to the test adapter and thereby cause the bumper to contact the plate and drive the test adapter along the track; initiate the connection between the test adapter and the test point; disconnect the test adapter and the test point upon a completion of the test program; and retract the plate to allow the test adapter to return to the initial position.

In an embodiment, further comprising: a frame securing the display and the screen, wherein the frame is adjustable to change at least one of a height and an angle of the frame.

In an embodiment, wherein the electrical test unit is secured to the frame and provides a notification indicative of an outcome of the test program.

In an embodiment, further comprising a plurality of storage receptacles for storing electrical components associated with the wire harness assembly, wherein the plurality of storage receptacles are positioned on or around a perimeter of the frame.

In an embodiment, wherein the mount further comprises a first lever to tighten the mount against the screen, and a second lever to secure the lateral position of the top protrusion.

In an embodiment, wherein the cable connector comprises a three-dimensional structure housing plurality of electrical contacts for connecting a plurality of cables corresponding to the digital wire harness diagram.

In an embodiment, wherein at least one of the attachment component and the cable connector are formed using an additive manufacturing process.

In an embodiment, a method for assembling and testing a wire harness, comprising: providing, at a display, information associated with a digital wire harness diagram; securing, on a screen positioned in front of the display, a mount, wherein the mount is secured to a cable connector; connecting a plurality of cables via the cable connector, wherein the plurality of cables are associated with a test point; initiating, by a computing device, a physical connection between the test point and a test adapter, wherein the test adapter is associated with an electrical testing unit, and where the electrical testing unit verifies electrical connections on a wire harness assembly; and executing, by the electrical testing unit, a test program associated with the digital wire harness diagram.

In an embodiment, wherein: securing the mount comprises attaching, to the screen, a rear protrusion extending from a base section of the mount, wherein the base section is rotatable around a point of attachment with the screen; and adjusting a lateral position of a top protrusion of the mount, wherein the top protrusion is secured to the cable connector, and wherein the top protrusion is laterally movable relative to the base section.

In an embodiment, further comprising: moving, by a conveyor system, the display and the screen between a first position to a second position; and executing the test program during a movement of the display and the screen between the first position and the second position.

In an embodiment, further comprising: moving the test adapter concurrently with the display and the screen to maintain an alignment between the test adapter and the test point; initiating the physical connection between the test adapter and the test point; and disconnecting the test adapter and the test point upon completion of the test program.

In an embodiment, further comprising: providing a result of the test program on at least one of: the electrical testing unit, the display, and output from a printer.

In an embodiment, a wire harness test system, comprising: at least one computing device comprising a processor and a memory comprising instructions, which when executed by the processor, cause the at least one computing device to: drive a motor to move at least one wire harness assembly station along a track, wherein the at least one wire harness assembly comprises a cable connector electrically connected to a set of cables, and a test point associated with the set of cables; when the at least one wire harness assembly station passes a first position, initiate a connection between the test point and a test adapter, wherein the test adapter is associated with an electrical testing unit, and wherein the test adapter moves along a second track after the wire harness assembly station passes the first position; execute, by the electrical testing unit, a test program to test an electrical connection of the at least one wire harness assembly; terminate the connection between the test point and the test adapter when the test program is complete; and generate output indicative of a result of the test program.

In an embodiment, further comprising instructions to cause the at least one computing device to upload the test program to the electrical testing unit.

In an embodiment, further comprising instructions to cause the at least one computing device to verify the test program is correctly associated with the at least one wire harness assembly, wherein verification is based on at least one of: a selection made on the electrical testing unit, a selection made on a display, and a barcode scan.

In an embodiment, wherein the result indicates a pass or fail of the at least one wire harness assembly, and wherein the output is provided on at least one of: the electrical testing unit, a display, and output from a printer.

In an embodiment, a system for testing wire harnesses, comprising: a first track defining an area for assembling wire harnesses; a motor connected to a frame supporting a wire harness assembly, wherein the motor is configured to move the frame along the first track, and wherein the wire harness assembly comprises a cable connector electrically connected to a set of cables, and a test point associated with the set of cables; a second track defining a travel path for a test adapter, wherein the test adapter is associated with an electrical testing unit for verifying electrical connections, a computing device comprising a processor and a memory configured to cause the computing device to: connect the test adapter and the test point, execute, by the electrical testing unit, a test program associated with the wire harness assembly, and disconnect the test adapter and the test point.

In an embodiment, wherein the test program occurs while the frame moves along the first track, and the test adapter moves along the second track.

In an embodiment, wherein the computing device is further configured to cause the test adapter to move between a retracted position and extended position, wherein the test adapter is connected to the test point in the extended position, and disconnected from the test point in the retracted position.

In an embodiment, wherein, when the frame passes a first position along the first track, the test adapter matches a speed of the frame, and becomes aligned with the test point.

In an embodiment, wherein the frame comprises a bumper, and wherein the computing device is further configured to: extend a plate connected to the test adapter when the bumper passes the first position, wherein the bumper contacts the plate and moves the test adapter along the second track; and disconnect the test adapter and the test point upon completion of the test program; and retract the plate after the test adapter and the test point are disconnected.

In an embodiment, wherein, test adapter returns to a starting position on the second track after being disconnected from the test point.

In an embodiment, wherein the computing device is configured to disconnect the test adapter and the test point when the test program is completed.

In an embodiment, wherein the frame secures a display providing information associated with a wire harness diagram, and a screen positioned in front of the display.

In an embodiment, wherein the frame comprises a set of wheels for movement along the first track.

In an embodiment, wherein the frame is adjustable to change at least one of a height and an angle of the frame.

In an embodiment, wherein, at least one of the following are positioned on or around a perimeter of the frame: a storage receptacle for at least one type of electrical component associated with the wire harness assembly, a testing unit, the computing device, a scanner, a printer, and a label machine.

In an embodiment, wherein the first track is a loop, and the second track is provided inside the loop.

In an embodiment, wherein the second track is a linear track provided behind the frame.

In an embodiment, wherein the first track and the second track are provided on a table.

In an embodiment, wherein the computing device is further configured to receive the test program from a remote computing device, and upload the test program to the electrical testing unit.

In an embodiment, wherein the motor is further connected to a second frame supporting a second wire harness assembly, wherein the motor is configured to drive the second frame along the first track.

In an embodiment, wherein the computing device is further configured to: execute a second test program to test the second wire harness assembly.

In an embodiment, a method for testing wire harnesses, comprising: moving a plurality of wire harness assembly stations along a first track, wherein the first track comprises a loop, and wherein a first wire harness assembly station comprises a frame supporting at least one cable connector, a set of cables connected to the cable connector, and a test point associated with the set of cables; when the first wire harness assembly station passes a first position along the first track, initiate a physical connection between a test adapter of an electrical testing unit, and the test point associated with the set of cables, wherein the test adapter starts at an initial position and moves along a second track during the physical connection with the test point; and disconnecting the test adapter and the test point when the electrical testing unit completes a test program to verify electrical connections via the test adapter and the test point.

In an embodiment, wherein the frame comprises a bumper, and wherein initiating the physical connection comprises: extending a plate connected to the test adapter when the bumper passes the first position, wherein the bumper contacts the plate and moves the test adapter along the second track; disconnecting the test adapter and the test point upon completion of the test program; and retracting the plate after the test adapter and the test point are disconnected, wherein the test adapter travels along the second track back to the initial position.

In an embodiment, further comprising: when a second wire harness assembly station passes the first position, initiate a physical connection between the test adapter and a test point associated with a second wire harness at the second wire harness assembly station, and execute a second test program by the electrical testing unit.

In an embodiment, method for manufacturing a wire harness, comprising: generating, using at least one design software, a cable connector based on a digital wire harness diagram, and a program to test electrical connections of a set of cables to be joined by the cable connector; producing the at least one cable connector using an additive manufacturing process; assembling the wire harness at an assembly station, wherein the wire harness comprises the cable connector, the set of cables, and a test point associated with the set of cables, and wherein the assembly station comprises a display providing the digital wire harness diagram, a screen positioned in front of the display, and a mount to secure the at least one cable connector to the screen; and establishing a connection between a test adapter associated with an electrical testing unit and the test point associated with the set of cables; executing, by the electrical testing unit, the program associated with the digital wire harness diagram; and generating output indicative of a result of the program.

In an embodiment, wherein assembling the wire harness further comprises: producing the mount using the additive manufacturing process.

In an embodiment, wherein the mount and the at least one cable connector are secured to the screen directly in front of a position of the cable connector on digital wire harness diagram.

In an embodiment, wherein the display provides a one-to-one scale image of the digital wire harness diagram.

In an embodiment, further comprising providing the digital wire harness diagram on two or more displays.

In an embodiment, wherein the result indicates a pass or fail of the wire harness, and wherein the output is provided on at least one of: the electrical testing unit, the display, and output from a printer.

In an embodiment, further comprising: prior to executing the program, verifying the program is correctly associated with the wire harness, wherein verifying comprises at least one of: making a selection on the electrical testing unit, making a selection on the display, and scanning a barcode.

In an embodiment, further comprising: driving, by a motor, the assembly station along a first track; driving a test adapter along a second track; and executing test program while the wire harness and the test adapter move, respectively, along the first track and the second track.

In an embodiment, further comprising: moving, by a conveyor system, the assembly station from a first position to a second position, wherein a first part of the wire harness is assembled at the first position, and a second part of the wire harness is assembled at the second position.

In an embodiment, further comprising: moving, by the conveyor system, the assembly station from a third position to a fourth position, wherein the program is executed between the third position and the fourth position.

In an embodiment, a system for manufacturing a wire harness, comprising: an assembly station comprising a display providing a digital wire harness diagram, a screen positioned in front of the display, and a mount to secure a cable connector to the screen; at least one computing device comprising a processor and a memory comprising instructions, which when executed by the processor, cause the at least one computing device to: generate the cable connector based on the digital wire harness diagram, and a program to test electrical connections of a set of cables to be joined by the cable connector; produce the cable connector using an additive manufacturing process; test a wire harness assembled from the digital wire harness diagram, wherein the wire harness comprises the cable connector, the set of cables, and a test point associated with the set of cables, and wherein the test of the wire harness further comprises instructions to: establish a connection between a test adapter associated with an electrical testing unit and the test point associated with the set of cables; and execute, by the electrical testing unit, the program associated with the digital wire harness diagram; and generate output indicative of a result of the program.

In an embodiment, wherein, at least one of the following are positioned on or around a perimeter of the frame: a storage receptacle for at least one type of electrical component associated with the wire harness, the electrical testing unit, the at least one computing device, a scanner, a printer and a label machine.

In an embodiment, wherein the mount comprises a base section having a rear protrusion to attach to the screen, and a top protrusion to secure the cable connector, wherein the base portion is rotatable around a point of attachment with the screen, and the top protrusion is movable to adjust a lateral position relative to the base section.

In an embodiment, wherein the screen comprises a plurality of holes to receive the rear protrusion of the mount.

In an embodiment, wherein the at least one computing device comprises instructions to further cause the at least one computing device to: move the test adapter between a retracted position and extended position, wherein the test adapter connects to the test point in the extended position, and disconnects from the test point in the retracted position.

In an embodiment, a non-transitory computer-readable medium comprising instructions stored thereon, which cause a computing device to at least: provide a digital wire harness diagram on a display associated with an assembly station; initiate production of a cable connector associated with the digital wire harness diagram, wherein the cable connector is formed from an additive manufacturing process; upload, to an electrical testing unit, a program to test electrical connections of a set of cables to be joined by the cable connector; test a wire harness assembled from the digital wire harness diagram, wherein the wire harness comprises the cable connector, the set of cables, and a test point associated with the set of cables, and wherein the test of the wire harness further comprises instructions to: establish a connection between a test adapter associated with the electrical testing unit and the test point associated with the set of cables; and execute, by the electrical testing unit, the program associated with the digital wire harness diagram; and generate output indicative of a result of the program.

In an embodiment, further comprising instructions to cause the computing device to: provide a one-to-one scale image of the digital wire harness diagram on the display.

In an embodiment, further comprising instructions to cause the computing device to: initiate the physical connection between the test adapter and the test point; and disconnect the test adapter and the test point upon completion of the program.

In an embodiment, further comprising instructions to cause the computing device to: provide the digital wire harness diagram on two or more displays.

In an embodiment, further comprising instructions to cause the computing device to: prior to executing the program, verify the program is correctly associated with the wire harness, wherein verifying comprises at least one of: making a selection on the electrical testing unit, making a selection on the display, and scanning a barcode.

In an embodiment, a wire harness test system, comprising: a wire harness assembly supported by a frame connected to a motor, wherein the motor moves the frame along a first track; a test adapter movable along a second track, wherein the test adapter is associated with an electrical testing unit to test electrical connections; and a computing device comprising a processor and a memory comprising instructions configured to cause the computing device to: execute a test program while the wire harness assembly and the test adapter move, respectively, along the first track and the second track.

In an embodiment, further comprising: a second wire harness assembly supported by a second frame connected to the motor, wherein the motor moves the second frame along the first track, and wherein the computing device is further configured to execute a second test program to test the second wire harness assembly while the wire harness assembly and the test adapter move, respectively, along the first track and the second track.

In an embodiment, further comprising instructions to cause the computing device to connect the test adapter and a test point associated with the wire harness assembly when the frame passes a first position along the first track, and disconnect the test adapter and the test point when the test program is completed.

In an embodiment, wherein when the test program is completed, the test adapter returns to an initial position on the second track.

In an embodiment, a method for testing a wire harness assembly, comprising: driving, by a motor, a first frame along a first track, wherein the first frame supports the wire harness assembly; driving a test adapter along a second track, wherein the test adapter is associated with an electrical testing unit for verifying electrical connections; and executing a test program while the wire harness assembly and the test adapter move, respectively, along the first track and the second track.

In an embodiment, further comprising: driving, by the motor, a second frame along the first track, the second frame supporting a second wire harness assembly; and executing a second test program while the second wire harness assembly moves along the first track.

In an embodiment, wherein the motor concurrently drives the first frame and the second frame along the first track.

In an embodiment, wherein the first track forms a loop, and wherein a perimeter of the first track defines at least one area for assembling wire harnesses.

In an embodiment, a system for wire harness testing, comprising: a conveyor system moving a wire harness assembly station from a first position to a second position, wherein the wire harness assembly station comprises a frame supporting at least one cable connector, a set of cables connected to the cable connector, and a test point associated with the set of cables; an electrical testing unit comprising a test adapter; and a computing device comprising a processor and a memory configured to cause the computing device to: execute, by the electrical testing unit, a first test program while the wire harness assembly station moves from the first position to the second position.

In an embodiment, wherein the conveyor system moves the wire harness assembly station along a looped path comprising the first position and the second position.

In an embodiment, wherein the conveyor system concurrently moves a second wire harness assembly station along the looped path.

In an embodiment, wherein the wire harness assembly station further comprises a plurality of storage receptacles for storing electrical components associated with the wire harness assembly station, wherein the plurality of storage receptacles are positioned on or around a perimeter of the frame.

As previously noted, the various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The example systems and components described herein may be configured differently than described. For example, elements may be added to, removed from, or rearranged compared to the disclosed example embodiments.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

The present disclosure describes particular embodiments and their detailed construction and operation. The embodiments described herein are set forth by way of illustration only and not limitation. Those skilled in the art will recognize, in light of the teachings herein, that there may be a range of equivalents to the exemplary embodiments described herein. Most notably, other embodiments are possible, variations can be made to the embodiments described herein, and there may be equivalents to the components, parts, or steps that make up the described embodiments. For the sake of clarity and conciseness, certain aspects of components or steps of certain embodiments are presented without undue detail where such detail would be apparent to those skilled in the art in light of the teachings herein and/or where such detail would obfuscate an understanding of more pertinent aspects of the embodiments.

The terms and descriptions used above are set forth by way of illustration only and are not meant as limitations. Those skilled in the art will recognize that those and many other variations, enhancements and modifications of the concepts described herein are possible without departing from the underlying principles of the invention. The scope of the invention should therefore be determined only by the following claims and their equivalents.

What is claimed:

1. A wire harness assembly system, comprising:
a display providing information associated with a digital wire harness diagram;
a screen positioned in front of the display;
a mount to secure a cable connector in front of the display, the mount comprising a base section having a rear protrusion to attach to the screen, and a top protrusion to secure the cable connector, wherein the base section is rotatable around a point of attachment with the screen, and the top protrusion is movable to adjust a lateral position relative to the base section;
an electrical testing unit for verifying electrical connections on a wire harness assembly;
a computing device comprising a processor and a memory comprising instructions, which when executed by the processor, cause the computing device to:
generate, on the display, the information associated with the digital wire harness diagram;
establish a connection between a test adapter associated with the electrical testing unit and a test point for a set of cables connected via the cable connector; and
execute, by the electrical testing unit, a test program associated with the digital wire harness diagram.

2. The wire harness assembly system of claim 1, further comprising:
a frame securing the display and the screen; and
a conveyor system comprising a motor configured to move the frame between a first position to a second position, wherein the electrical testing unit executes the test program during a movement of the frame between the first position and the second position.

3. The wire harness assembly system of claim 2, wherein the test adapter is movable along a track, wherein the test adapter moves concurrently with the frame maintain the connection with the test point during execution of the test program, and wherein the test adapter returns to an initial position on the track after completion of the test program.

4. The wire harness assembly system of claim 3, wherein the track is positioned behind the frame.

5. The wire harness assembly system of claim 3, wherein the frame comprises a bumper, and wherein the computing device is further configured to:
when the frame passes the first position, extend a plate connected to the test adapter and thereby cause the bumper to contact the plate and drive the test adapter along the track;
initiate the connection between the test adapter and the test point;
disconnect the test adapter and the test point upon a completion of the test program; and
retract the plate to allow the test adapter to return to the initial position.

6. The wire harness assembly system of claim 1, further comprising: a frame securing the display and the screen, wherein the frame is adjustable to change at least one of a height and an angle of the frame.

7. The wire harness assembly system of claim 6, wherein the electrical test unit is secured to the frame and provides a notification indicative of an outcome of the test program.

8. The wire harness assembly system of claim 6, further comprising a plurality of storage receptacles for storing electrical components associated with the wire harness assembly, wherein the plurality of storage receptacles are positioned on or around a perimeter of the frame.

9. The wire harness assembly system of claim 1, wherein the mount further comprises a first lever to tighten the mount against the screen, and a second lever to secure the lateral position of the top protrusion.

10. The wire harness assembly system of claim 1, wherein the cable connector comprises a three-dimensional structure housing plurality of electrical contacts for connecting a plurality of cables corresponding to the digital wire harness diagram.

11. The wire harness assembly system of claim 10, wherein at least one of the attachment component and the cable connector are formed using an additive manufacturing process.

12. A method for assembling and testing a wire harness, comprising:
providing, at a display, information associated with a digital wire harness diagram;
securing, on a screen positioned in front of the display, a mount, wherein the mount is secured to a cable connector;
connecting a plurality of cables via the cable connector, wherein the plurality of cables are associated with a test point;
initiating, by a computing device, a physical connection between the test point and a test adapter, wherein the test adapter is associated with an electrical testing unit, and where the electrical testing unit verifies electrical connections on a wire harness assembly; and
executing, by the electrical testing unit, a test program associated with the digital wire harness diagram.

13. The method of claim 12, wherein:
securing the mount comprises attaching, to the screen, a rear protrusion extending from a base section of the mount, wherein the base section is rotatable around a point of attachment with the screen; and
adjusting a lateral position of a top protrusion of the mount, wherein the top protrusion is secured to the cable connector, and wherein the top protrusion is laterally movable relative to the base section.

14. The method of claim 12, further comprising:
moving, by a conveyor system, the display and the screen between a first position to a second position; and
executing the test program during a movement of the display and the screen between the first position and the second position.

15. The method of claim 14, further comprising:
moving the test adapter concurrently with the display and the screen to maintain an alignment between the test adapter and the test point;
initiating the physical connection between the test adapter and the test point; and
disconnecting the test adapter and the test point upon completion of the test program.

16. The method of claim 12, further comprising: providing a result of the test program on at least one of: the electrical testing unit, the display, and output from a printer.

17. A wire harness test system, comprising:
at least one computing device comprising a processor and a memory comprising instructions, which when executed by the processor, cause the at least one computing device to:
drive a motor to move at least one wire harness assembly station along a track, wherein the at least one wire harness assembly comprises a cable connector electrically connected to a set of cables, and a test point associated with the set of cables;
when the at least one wire harness assembly station passes a first position, initiate a connection between the test point and a test adapter, wherein the test adapter is associated with an electrical testing unit, and wherein the test adapter moves along a second track after the wire harness assembly station passes the first position;
execute, by the electrical testing unit, a test program to test an electrical connection of the at least one wire harness assembly;
terminate the connection between the test point and the test adapter when the test program is complete; and
generate output indicative of a result of the test program.

18. The wire harness test system of claim 17, further comprising instructions to cause the at least one computing device to upload the test program to the electrical testing unit.

19. The wire harness test system of claim 17, further comprising instructions to cause the at least one computing device to verify the test program is correctly associated with the at least one wire harness assembly, wherein verification is based on at least one of: a selection made on the electrical testing unit, a selection made on a display, and a barcode scan.

20. The wire harness test system of claim 17, wherein the result indicates a pass or fail of the at least one wire harness assembly, and wherein the output is provided on at least one of: the electrical testing unit, a display, and output from a printer.
